(19) United States
(12) Patent Application Publication
(10) Pub. No.: US 2006/0231287 A1
(43) Pub. Date: Oct. 19, 2006

(54) Wiring structure and recording apparatus and electronic apparatus including wiring structure

(75) Inventor: Teruo Nakayama, Nagano (JP)

Correspondence Address: SUGHRUE MION, PLLC, 2100 PENNSYLVANIA AVENUE, N.W., SUITE 800, WASHINGTON, DC, 20037, US

(73) Assignee: SEIKO EPSON CORPORATION

(21) Appl. No.: 11/392,623

(22) Filed: Mar. 30, 2006

(30) Foreign Application Priority Data
Mar. 30, 2005 (JP) P2005-097455

(51) Int. Cl. H05K 1/00

(52) U.S. Cl. 174/250

(57) ABSTRACT

A wiring structure includes a substrate, a first circuit and a second circuit, provided on the substrate, a first wire, provided on the substrate, and connecting the first circuit and the second circuit, the first wire having a first length, and a second wire, provided on the substrate, and connecting the first circuit and the second circuit, the second wire having the first length and including a first swirled part.

### BACKGROUND OF THE INVENTION

The present invention relates to a wiring structure, particular to a wiring structure of equal-length wires, which is provided on a substrate or the like to be used in an electronic apparatus such as a recording apparatus.

A printed-circuit board is embedded in the electronic apparatus such as the recording apparatus. On the printed-circuit board, there are mounted a circuit for transmitting a plurality of synchronized signals, and another circuit for receiving the signals. The synchronized signals have to be received substantially simultaneously by another circuit. In the case of no substantially simultaneous reception, it cannot be denied that the circuit provided on the printed-circuit board may cause an erroneous action or an erroneous inaction. Therefore, the time periods for the individual signals to be transferred from one circuit to another, that is, the signal transmission delay time periods are equalized. Specifically, the circuits are connected through equal-length wires.

Depending on the layout of the printed-circuit board, however, the wiring lengths of the equal-length wires may be unable to be equalized merely by connecting the circuits. In the related art, therefore, a detoured-extension wiring part is formed in the equal-length wires so as to adjust the lengths. Specifically, the detoured-extension wiring part, which is adjusted in length according to the largest wiring length of the equal-length wires in the case of connecting the individual circuits, is formed in another equal-length wire. In an detoured-extension wiring part (as referred to JP-A-2003-152290, for example), the equal-length wires are alternately extended in the so-called meandering shape.

In the equal-length wiring structure of the related art, the detoured-extension wiring part is alternately extended in the so-called meandering shape so that many turned parts exist. At these turned parts, reflections easily occur with a signal to pass through the detoured-extension wiring part thereby to cause the radiation noises. The radiation noises thus caused propagate to the casing of the electronic apparatus such as the recording apparatus so that they are released to the outside. According to the standards, however, the maximum allowance is regulated on the electromagnetic waves to be irradiated from the entire electronic apparatus such as the recording apparatus. At a large value of the radiation noises, therefore, the electromagnetic waves to be released to the outside are enlarged to raise a problem that the electromagnetic waves are not at or lower than the maximum allowance. When the reflections occur, moreover, the waveforms of the signals may be disturbed to exert influences on the transmissions of the plural signals.

In the equal-length wiring structure forming the detoured-extension wiring part of the meandering shape, moreover, the detoured-extension wiring part of the meandering shape has a length and a width of some extent as a whole so that it needs a relatively large space on the substrate. This may restrict the layout or the like of another circuit on the substrate.

### SUMMARY

It is therefore an object of the invention to provide a wiring structure which is enabled to reduce the noises to be irradiated from equal-length wires by forming the equal-length wires into a shape hard to cause reflections even if it transmits and receives a plurality of noises, and a recording apparatus and an electronic apparatus having that equal-length wiring structure.

It is therefore another object of the invention to provide a wiring structure which is enabled to reduce the space for equal-length wires on a substrate while reducing the noises to be irradiated from the equal-length wires, by modifying the shapes of the equal-length wires, and a recording apparatus and an electronic apparatus having that equal-length wiring structure.

In order to achieve the object, according to the invention, there is provided a wiring structure comprising:

a substrate;

a first circuit and a second circuit, provided on the substrate;

a first wire, provided on the substrate, and connecting the first circuit and the second circuit, the first wire having a first length; and

a second wire, provided on the substrate, and connecting the first circuit and the second circuit, the second wire having the first length and including a first swirled part.

Here, the first wire is of such one wire of the equal-length wires connecting the first circuit and the second circuit as does not form the detoured-extension wiring part. The second wire is such one or more wires of the equal-length wires connecting the first circuit and the second circuit as form the detoured-extension wiring part. According to this configuration, a part of each of one or more forming that detoured-extension wiring part, i.e., the detoured-extension wiring part is formed into the swirled shape.

With this configuration, even if the plural signals are transmitted or received, therefore, the reflections are hard to occur unlike the detoured-extension wiring part of the meandering shape, so that the noises to be irradiated from the equal-length wires can be reduced. Moreover, the swirl-shaped detoured-extension wiring part does not need such a large state as a whole so that it can also reduce the space for the plural equal-length wires provided on the substrate.

The wiring structure may further include a third wire, provided on the substrate, and connecting the first circuit and the second circuit, the third wire having the first length and including a second swirled part. The first swirled part and the second swirled part may be arrayed in a first direction.

The first wire may include a first part extending in the first direction and a second part extending in a second direction different from the first direction, and a length of the first part may be longer than a length of the second part.

In this case, another circuit can be easily arranged in the space on the substrate having no equal-length wire, so that the space on the substrate can be effectively exploited.

The substrate may include a main control substrate.

Many circuits for communicating the plural signals are provided on the main control substrate so that the radiation noises easily occur. However, in this case, the radiation noises on the main control substrate can be efficiently reduced.

In order to achieve the object, according to the invention, there is also provided a recording apparatus, operable to record information to a medium, thereby recording is performed, the recording apparatus comprising:

a controller, operable to control the recording; and

the wiring structure according to claim 1, provided in the controller.

In this case, it is possible to provide the recording apparatus which is hard to cause the reflections, even if the plural signals are transmitted or received, thereby to reduce the noises to be irradiated from the equal-length wires.

In order to achieve the object, according to the invention, there is also provided an electronic apparatus, operable to perform a predetermined operation, the electronic apparatus comprising:

a controller, operable to control the predetermined operation; and the wiring structure according to claim 1, provided in the controller.

In this case, it is possible to provide the electronic apparatus which is hard to cause the reflections, even if the plural signals are transmitted or received, thereby to reduce the noises to be irradiated from the equal-length wires.

### BRIEF DESCRIPTION OF THE DRAWINGS

FIG. 1 is a perspective view showing the exterior of a recording apparatus according to an embodiment of the invention;

FIG. 2 is a perspective view showing a main control substrate and a power source substrate, which are mounted in the recording apparatus, and their peripheral vicinities;

FIG. 3 is an enlarged top plan view of the periphery of a CPU of the main control substrate;

FIG. 4 is a sectional view, as taken in the direction of arrows A-A, of the main control substrate 11 shown in FIG. 3;

FIG. 5 is a top plan view showing the peripheral vicinity of the swirl-shaped detoured-extension wiring part according to a first embodiment of the invention;

FIG. 6 is a top plan view showing the peripheral vicinity of a swirl-shaped detoured-extension wiring part according to a second embodiment of the invention;

FIG. 7 is a top plan view showing the peripheral vicinity of the detoured-extension wiring part of the related art; and

FIGS. 8A to 8C present simple diagrams showing such impedances of two adjacent wires as are changed by signals to pass through the two wires.

### DETAIL DESCRIPTION OF PREFERRED EMBODIMENTS

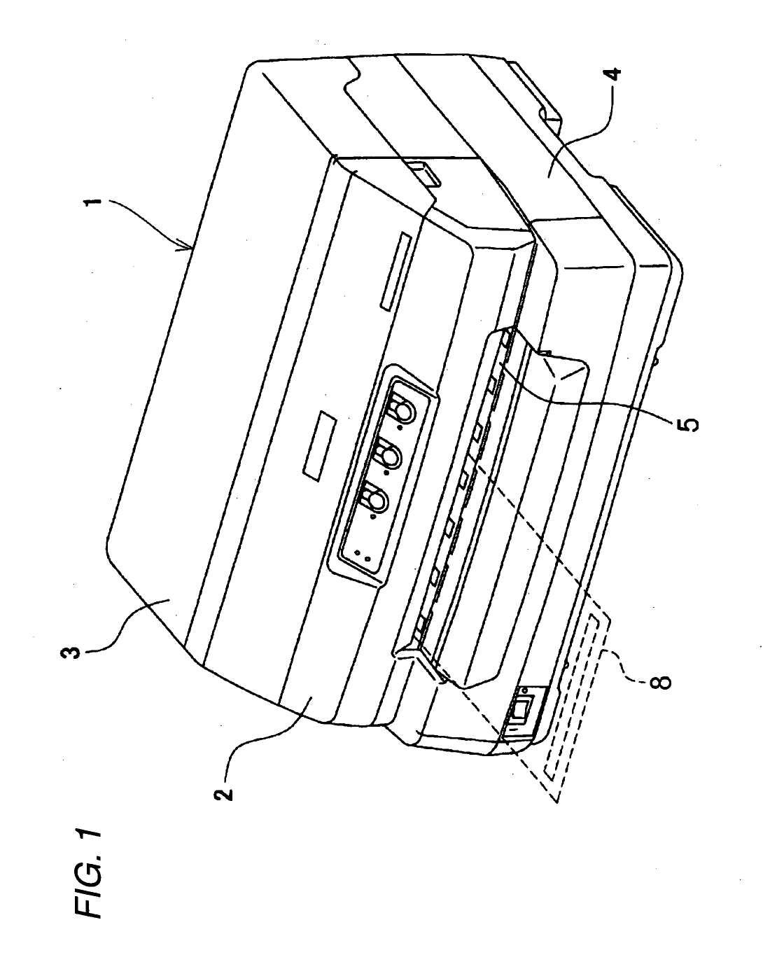

A first embodiment of the invention is described with reference to FIG. 1 to FIG. 5 by taking up a recording apparatus 1 as one example of the electronic apparatus according to the invention. Here, the embodiment to be described in the following should not limit the invention according to claims, and all the combinations of the characteristics described in this embodiment are not essential for the solving means of the invention.

FIG. 1 is a perspective view showing the exterior of the recording apparatus 1 according to the embodiment of the invention. The recording apparatus 1 shown in FIG. 1 is constituted to include an upper cover 2, an upper housing 3 and a lower housing 4, and is equipped on its front face with an opened slot 5. When a medium 8 to be recorded is inserted into the slot 5, it is recorded by the recording apparatus 1 and discharged from the slot 5.

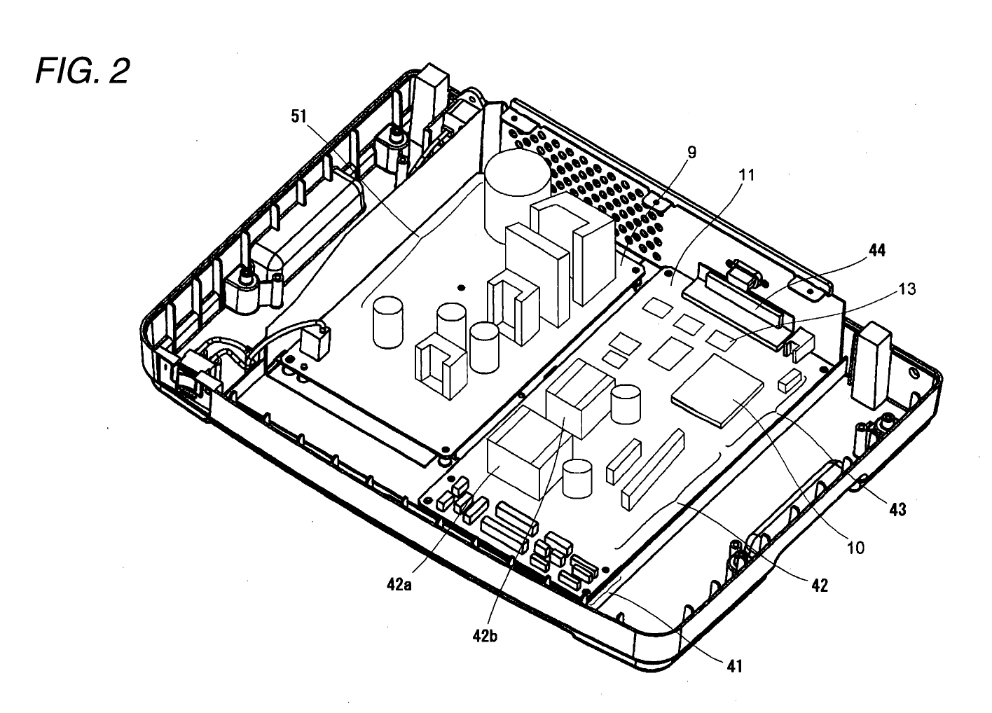

FIG. 2 is a perspective view showing a main control substrate 11 and a power source substrate 9, which are mounted in the recording apparatus 1, and their peripheral vicinities. In the vicinity of the central right part of FIG. 2, there are mounted power-family parts or logic-family parts, and there is arranged the main control substrate 11 for controlling the individual devices mounted in the recording apparatus 1. On the left side of the main control substrate 11, moreover, there is horizontally arranged the power source substrate 9, on which the primary side parts group 51 of the power source is mounted.

The main control substrate 11 includes a connector area 41 having various connectors arranged therein, a power-family parts mounting area 42 having the power-family parts mounted therein, and a logic-family parts mounting area 43 having the logic-family parts mounted therein.

In the power-family parts mounting area 42, for example, there are mounted the power-family parts such as a motor driver or a head driver, and heat sinks 42a and 42b for releasing the heat generated by the power-family parts.

In the logic-family parts mounting area 43, there are mounted logic-family parts such as a CPU 10 or a RAM 13. The logic-family parts mounting area 43 is disposed at such a position as to have easy access to an interface unit 44 arranged on the back face of the recording apparatus 1.

The various parts, which are mounted in the connector area 41, the power-family parts mounting area 42 and the logic-family parts mounting area 43, are connected through the not-shown circuit pattern provided in the main control substrate 11.

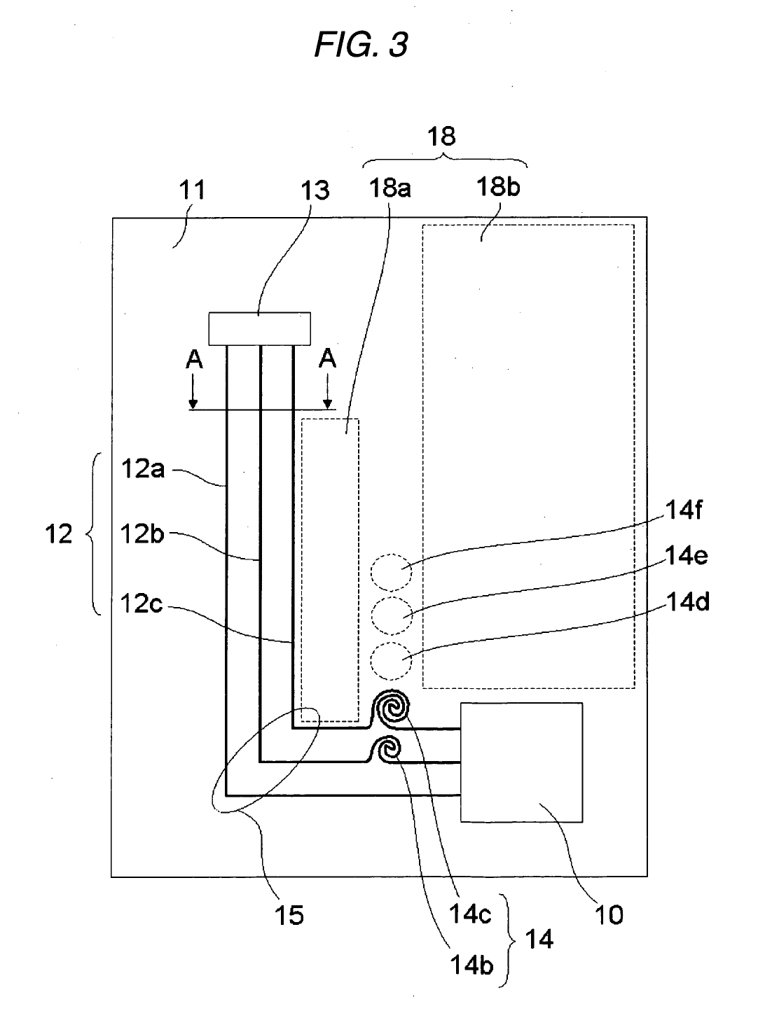

FIG. 3 is an enlarged top plan view of the periphery of the CPU 10 of the main control substrate 11, to which a swirl-shaped equal-length wiring structure is applied. As shown in FIG. 3, the main control substrate 11 according to the first embodiment has the CPU 10 and the RAM 13 mounted as the electronic parts (or a circuit) on its surface. On the main control substrate 11, moreover, there are provided three equal-length wires 12 (12a, 12b and 12c) for connecting the CPU 10 and the RAM 13. Here, the CPU 10 executes a logical operation by a synchronous type control, and transmits data signals and address signals synchronized with clock signals, as outputs. The RAM 13 receives the signals (i.e., the clock signals, the data signals and the address signals) transmitted from the CPU 10, and stores the data at predetermined addresses. For this, it is necessary to equalize the time periods for the signals to be transmitted from the CPU 10 to the RAM 13, i.e., signal propagation delay time periods. Thus, the CPU 10 and the RAM 13 are connected by the equal-length wires of the equal wiring length.

For conveniences of the layout of the main control substrate 11, however, the CPU 10 cannot be arranged straight of the RAM 13, as shown in FIG. 3. In this case, a curved corner 15 is formed midway of the equal-length wires 12. With this curved corner 15, however, the equal-length wire 12c of the innermost side and the equal-length wire 12a of the outermost side of the curved corner 15 have different wiring lengths so that their wiring lengths cannot be equalized. According to the longest wiring length of the equal-length wire 12a, therefore, the wiring lengths of the equal-length wires 12b and 12c are adjusted.

According to the wiring length of the equal-length wire 12a made the largest in case the CPU 10 and the RAM 13 are connected, more specifically, detoured-extension wiring parts 14 (i.e., 14b and 14c) having been lengthwise adjusted are formed in the equal-length wires 12b and 12c, respectively. In FIG. 3, the detoured-extension wiring parts 14 are formed in the swirled shapes. Here, the detoured-extension wiring part 14b has a smaller number of turns than that of the detoured-extension wiring part 14c. By changing the number of turns, the difference in the wiring length between the equal-length wire 12c curved on the innermost side of the curved corner 15 and the equal-length wire 12b curved on the center is adjusted. By forming the detoured-extension wiring parts 14 into the swirled shapes, the reflection can be made hard to occur thereby to reduce the radiation noises, as will be described hereinafter.

In FIG. 3, moreover, there are shown a space 18 (in dotted lines) and detoured-extension wiring parts 14d, 14e and 13f (in dotted lines). The space 18 is provided for the main control substrate 11 not having the equal-length wires 12 provided therein. In the space 18, there are provided the remaining circuits (e.g., mounted parts and wires) of the main control substrate 11. Moreover, the detoured-extension wiring parts 14d, 14e and 14f are formed in case the number of the equal-length wires 12 is increased, as will be described hereinafter. In the first embodiment, the detoured-extension wiring parts 14 are formed at substantially identical portions in the longitudinal direction of the individual equal-length wires 12. As shown in FIG. 3, specifically, the detoured-extension wiring parts 14b and 14c are arrayed in one row in the longitudinal direction. By these parts, the space 18 is divided into spaces 18a and 18b having substantially rectangular shapes. This division makes it possible to arrange the remaining circuits of the main control substrate 11 easily in the spaces 18a and 18b. It is also possible to exploit the space 18 effectively.

If the number of the equal-length wires 12 is increased, the detoured-extension wiring parts 14d, 14e and 14f are formed, as shown in FIG. 3. In this case, too, the detoured-extension wiring parts 14b to 14f are arrayed in one row in the longitudinal direction. As a result, the spaces 18a and 18b are also reduced in size according to the equal-length wires 12 but are not changed in shape. It is, therefore, possible to arrange the remaining circuits easily in the spaces 18a and 18b.

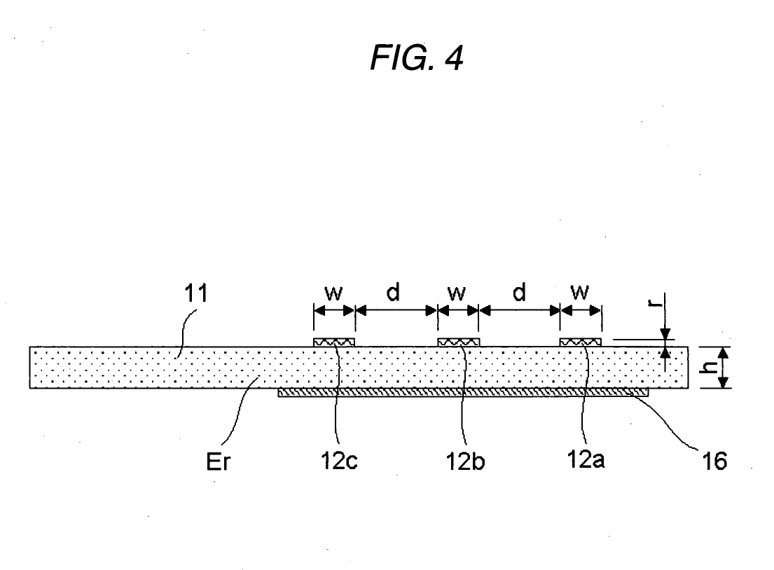

FIG. 4 is a sectional view, as taken in the direction of arrows A-A, of the main control substrate 11 shown in FIG. 3. As shown in FIG. 4, the equal-length wires 12a, 12b and 12c having a wiring width w and a wiring thickness r are provided on the surface of the main control substrate 11. Moreover, the equal-length wires 12a and 12b and the equal-length wires 12b and 12c are arranged across a clearance d therebetween. On the other hand, the main control substrate 11 is formed by printing copper foil on an insulating material having dielectric constant Er and a thickness h. A ground pattern 16 is provided on that face of the main control substrate 11 which does not have the equal-length wires 12. Although not shown in FIG. 4, moreover, the detoured-extension wiring parts 14 (as referred to FIG. 3) are so formed at the equal-length wires 12b and 12c as to adjust the wiring lengths.

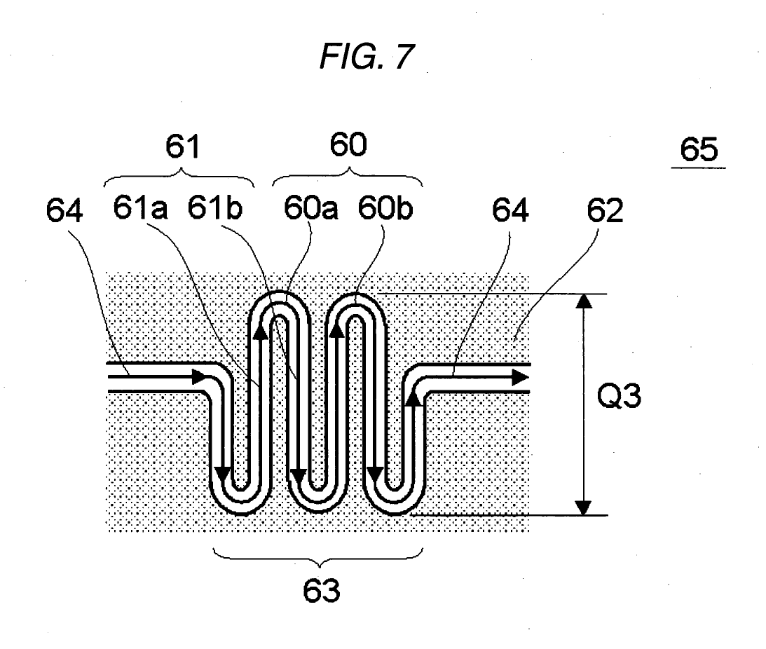

Next, a detoured-extension wiring part 63 of a meandering shape of the related art is described with reference to FIG. 7, before the swirl-shaped detoured-extension wiring parts 14 are described. FIG. 7 is a top plan view showing the peripheral vicinity of the detoured-extension wiring part 63 of the related art. As shown in FIG. 7, an equal-length wire 65 is constituted to include the detoured-extension wiring part 63 and a non-detoured-extension part 64. Here, the non-detoured-extension part 64 is the wiring other than the detoured-extension wiring part 63 of the equal-length wire 65. The detoured-extension wiring part 63 is formed in the meandering shape. Moreover, a ground pattern 62 is formed to surround the periphery of the detoured-extension wiring part 63. This detoured-extension wiring part 63 is constituted to include a plurality of turned parts 60 and a plurality of straight parts 61, which are repeatedly combined to adjust the wiring length of the equal-length wire 65.

The detoured-extension wiring part 63 is formed to adjust the wiring length of the equal-length wire 65, as described hereinbefore. On the other hand, the ground pattern 62 is formed to absorb the radiation noises generated due to the reflections at the turned parts 60, thereby to transmit the radiation noises to the not-shown shielded plate in the recording apparatus 1. The radiation noises transmitted to the not-shown shielded plate are either synthesized to converge with the remaining radiation noises while passing through the not-shown shielded plate or consumed in the resistance components of the not-shown shielded plate. In case of many radiation noises generated, however, all the radiation noises are not converged or consumed, even if the ground pattern 62 is formed to transmit the radiation noises to the not-shown shielded plate. The remaining radiation noises propagated to the not-shown casing of the recording apparatus 1 so that they are released to the outside. According to the standards, the maximum allowance is specified on the electromagnetic waves to be irradiated from the entirety of the recording apparatus 1 so that the electromagnetic waves to be emitted to the outside for the high radiation noises. This raised a problem that the electromagnetic waves did not become the maximum allowance or less. As a result, restrictions are made on the layout or the like of the remaining circuits on the main control substrate 11.

In case the ground pattern 62 is formed, on the other hand, it has to be interposed between the two straight parts 61 connected through the turned parts 60, e.g., between straight parts 61a and 61b. This interposition raised a problem that the spacing between the straight parts 61a and 61b is enlarged. This enlargement of the spacing of the straight parts 61 widened the space for the detoured-extension wiring part 63. In order to reduce the radiation noises, moreover, the detoured-extension wiring part 63 is formed into a shape to make the turned parts 60 as small as possible. Specifically, the length of the straight parts 61 is enlarged to alternate the difference from the wiring length of the remaining equal-length wiring while reducing the turned parts 60. Since the length of the straight parts 61 is enlarged, however, the exterior size Q3 of the detoured-extension wiring part 63 is enlarged to raise a problem that any other equal-length wire could not be provided near the equal-length wire 65. In short, the clearance d between the wires is increased.

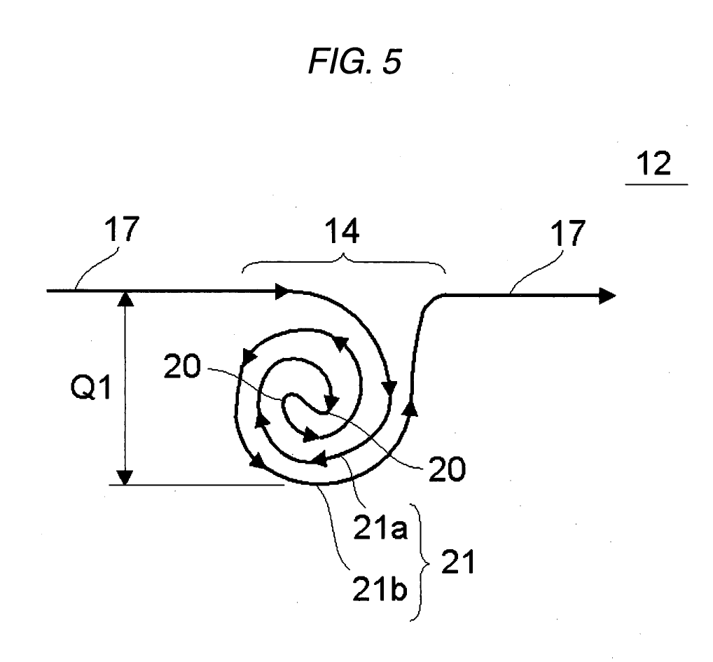

Thus, there is proposed the swirl-shaped detoured-extension wiring part 14. This swirl-shaped detoured-extension wiring part 14 is described with reference to FIG. 5. FIG. 5 is a top plan view showing the peripheral vicinity of the swirl-shaped detoured-extension wiring part 14 according to the first embodiment. As shown in FIG. 5, the equal-length wire 12 is constituted to include the detoured-extension wiring part 14 and non-detoured-extension parts 17. Here, these non-detoured-extension parts 17 indicate the wires of the equal-length wire 12 other than the detoured-extension wiring part 14. Here, the swirl-shaped detoured-extension wiring part 14 is formed to include two turned parts 20 and curved parts 21. By reducing the number of the turned parts 20 to two, reflecting portions are reduced to make the reflections hard to occur. By disposing the two turned parts 20 at the central part of the swirled shape, moreover, the impedance of the detoured-extension wiring part 14 is more homogenized, as will be described hereinafter, thereby to make the reflections harder to occur. As a result, the radiation noises can be made hard to occur so that they can be reduced. Therefore, the detoured-extension wiring part 14, as shown in FIG. 5, does not need the ground pattern 62 unlike the detoured-extension wiring part 63 of the related art, as shown in FIG. 7, so that no ground pattern is formed in the periphery of the detoured-extension wiring part 14. This makes it possible to make the spacing of the curved parts 21 such as the spacing between curved parts 21a and 21b narrower than that of the related art. As a result, the space can be made less than the related art. Since the ground pattern 62 is not needed, moreover, the exterior size Q1 of the swirl-shaped detoured-extension wiring part 14 can be made narrower under the same conditions than the exterior size Q3 (as referred to FIG. 7) of the detoured-extension wiring part 63 having the meandering shape of the related art. As a result, for example, the equal-length wire 12c can be provided closer to the other equal-length wire 12b than the related art, thereby to reduce the clearance d between the wires more than the related art.

At the same step as that of forming the detoured-extension wiring part 63 of the related art, moreover, the swirl-shaped detoured-extension wiring part 14 can be provided in the main control substrate 11. By forming the swirl-shaped detoured-extension wiring part 14, therefore, the effects can be acquired without adding any step.

With reference to FIG. 4 to FIG. 8C, here is described the mechanism for making the generation of reflections easy in the wiring of the meandering shape of the related art but difficult in that of the swirled shape of the invention. It is generally known that the reflections easily occur in the wiring to be passed by a plurality of synchronized signals, as the impedance of the wiring becomes heterogeneous. Therefore, the impedance is described at first with reference to FIG. 4. As has been described hereinbefore, the main control substrate 11 is constituted to include the insulating material having the dielectric constant Er and the thickness h, and is formed by printing the copper foil of the wiring width w and the wiring thickness r, i.e., the equal-length wire 12 on the surface of the insulating material. Here, the impedance of the equal-length wire 12 is uniquely determined from the wiring width w, the wiring thickness r, the thickness h of the insulating material, and the dielectric constant Er of the insulating material of the main control substrate 11.

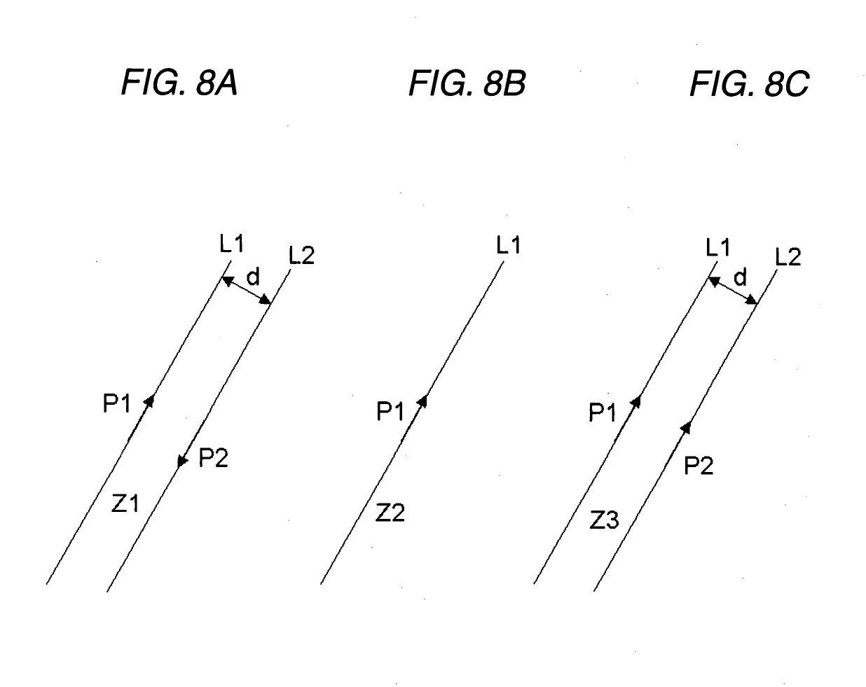

For example, however, the impedance of the equal-length wire 12c may be so influenced by the signal to pass through the equal-length wire 12c and another adjacent equal-length wire 12c that it may change from the uniquely determined value. The mechanism for the impedance of the equal-length wire 12c to be changed by the signals to pass through the equal-length wires 12c and 12b is described with reference to FIGS. 8A to 8C.

FIGS. 8A to 8C present simple diagrams showing such impedances of two wires L1 and L2 as are changed by signals P1 and P2 to pass through the two adjacent wires L1 and L2. FIGS. 8A to 8C show the two wires L1 and L2, the signal P1 to pass through the wire L1, and the signal P2 to pass through the wire L2. The two wires are provided and spaced by the clearance d. It is generally known that the signals P1 and P2 interfere with each other to change the impedance when they pass through the two adjacent wires L1 and L2. In FIGS. 8A to 8C, the individual impedances are compared assuming the cases of three kinds. All the remaining conditions not shown in FIGS. 8A to 8C are made identical.

FIG. 8A is a simplified diagram showing an impedance Z1 of the case, in which the signal P1 and the signal P2 are transmitted in the opposite directions; FIG. 8B is a simplified diagram showing an impedance Z2 of the case, in which no other adjacent wire is around the wire L1; and FIG. 8C is a simplified diagram showing an impedance Z3 of the case, in which the signal P1 and the signal P2 are transmitted in the same direction. In the case of the three kinds, the impedances become larger in the order of Z1, Z2 and Z3. From this, it is found that the impedances are changed by the transmission directions of the signals to pass through the adjacent wires. Here, the changes the more largely appear, as the clearance d between the wires is the smaller, that is, as the wires are the closer to each other.

Here are described the changes in the impedances of the detoured-extension wiring part 63 shown in FIG. 7 and the detoured-extension wiring part 14 shown in FIG. 5. In FIG. 7, the arrows of the detoured-extension wiring part 63 indicate the directions, in which the signals are transmitted. For example, therefore, the signal to pass through the straight part 61a and the signal to pass through the straight part 61b are directionally reversed. As a result, the impedances of the straight part 61a and the straight part 61b are smaller than that of the non-detoured-extension part 64. On the other hand, the signal to pass through the turned part 60a and the signal to pass through the adjacent turned part 60b are in the same direction, so that the impedances of the turned part 60a and the turned part 60b are larger than that of the non-detoured-extension part 64. Therefore, the impedance of the straight part 61 and the impedance of the turned part 60 are so heterogeneous that the reflections easily occur between the straight part 61 and the turned part 60. Moreover, the detoured-extension wiring part 63 has such a structure that the reflections easily occur, because it is formed of the plural turned parts 60.

In the detoured-extension wiring part 14 shown in FIG. 5, on the other hand, the detoured-extension wiring part 14 is constituted to include the two turned parts 20 and the curved parts 21 so that the reflecting portions are less to cause less reflections. In FIG. 5, moreover, the arrows of the swirl-shaped detoured-extension wiring part 14 indicate the direction, in which the signals are transmitted. The signal to pass through the curved parts 21a and the signal to pass through the adjacent curved parts 21b are in the opposite directions. As a result, the impedances of the curved parts 21a and the curved parts 21b are less than the impedances of the non-detoured-extension parts 17. On the other hand, the turned parts 20 are located at the center of the swirl-shaped detoured-extension wiring part 14 so that the signal to pass through the turned parts 20 and the signal to pass through the adjacent curved part 21a or 21b are in the opposite directions. Therefore, the impedance of the turned parts 20 becomes smaller than the impedance of the non-detoured-extension part 17. As a result, the impedance in the swirl-shaped detoured-extension wiring part 14 can be more homogenized than that of the detoured-extension wiring part 63 of the related art. Therefore, the swirl-shaped detoured-extension wiring part 14 has such a structure as to cause the reflections hardly.

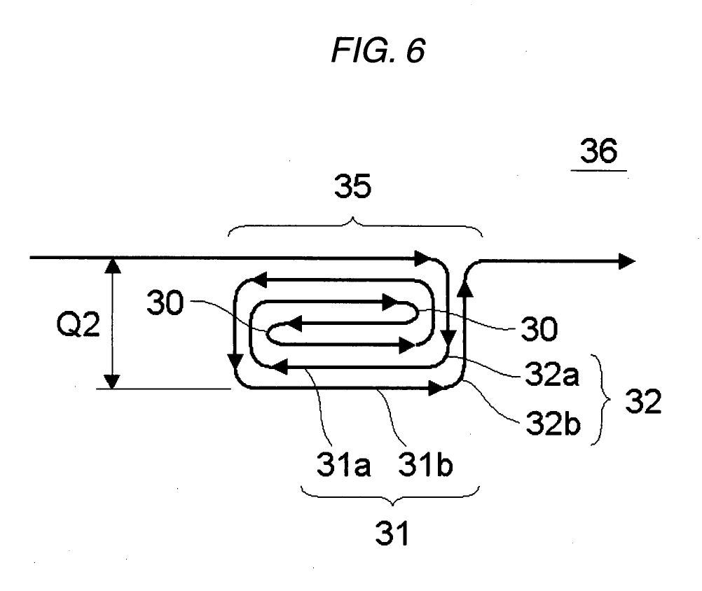

Next, a second embodiment of the invention is described with reference to FIG. 6. Here, the embodiment to be described hereinafter should neither limit the invention according to the claims, nor are essential all the combinations of the characteristics described in this embodiment, for the means for solving the invention. Moreover, the detailed description of the second embodiment is omitted by designating the parts similar to those of the first embodiment by the common reference numerals.

The not-shown main control substrate according to the second embodiment of the invention is included, like the first embodiment, in the recording apparatus 1 shown in FIG. 1. Moreover, the power source substrate 9 shown in FIG. 2 is arranged on the left side of the not-shown main control substrate. Moreover, an equal-length wire 36 including a swirl-shaped detoured-extension wiring part 35 according to the second embodiment is arranged in the not-shown main control substrate.

FIG. 6 is a top plan view showing the peripheral vicinity of the swirl-shaped detoured-extension wiring part 35 according to the second embodiment. As shown in FIG. 6, the swirl-shaped detoured-extension wiring part 35 is formed to include two turned parts 30, straight parts 31 and curved parts 32. By reducing the number of the turned parts 30 to two, as in the first embodiment, the reflecting portions are reduced to make the reflections hard to occur. By disposing the two turned parts 30 at the central part of the detoured-extension wiring part 35, as in the first embodiment, the impedance of the detoured-extension wiring part 35 is more homogenized to make the reflections harder to occur. As a result, the radiation noises can be made hard to occur so that they can be reduced. Therefore, the swirl-shaped detoured-extension wiring part 35, as shown in FIG. 6, does not need the ground pattern 62 unlike the detoured-extension wiring part 63 of the related art, as shown in FIG. 7. Therefore, the spacing of the straight parts 31, such as the spacing between the straight parts 31a and 31b can be made narrower than that of the related art. Likewise, the spacing of the curved parts 32, such as the spacing between the curved parts 32a and 32b can be made narrower than that of the related art. As a result, the space can be made less than that of the related art.

Moreover, the swirl-shaped detoured-extension wiring part 35 according to the second embodiment is equipped with the straight parts 31 so that it has such a shape that the detoured-extension wiring part 14 (as referred to FIG. 5) according to the first embodiment is pushed down. This makes the exterior size Q2 of the swirl-shaped detoured-extension wiring part 35 narrower than the exterior size Q1 (as referred to FIG. 5) of the first embodiment. As a result, the equal-length wire 36 and another equal-length wire can be provided closer to each other, by applying the swirl-shaped detoured-extension wiring part 35 according to the second embodiment, than that of the case, in which the detoured-extension wiring part 14 (as referred to FIG. 5) is applied. In short, it is possible to make the clearance d between the wires the less.

According to the equal-length wiring structure according to the first embodiment, as has been described hereinbefore, the signals are transmitted and received by connecting the CPU 10 or the first circuit provided on the main control substrate 11 and the RAM 13 or the second circuit provided on the main control substrate 11 and spaced from the CPU 10 through the plural equal-length wires 12 provided on the main control substrate 11. Of the plural equal-length wires 12, moreover, the detoured-extension wiring parts 14b and 14c or the parts of the wires 12b and 12c other than the predetermined wire 12a are formed in the swirled shape.

As a result, even if the plural signals are transmitted or received, the reflections are hard to occur unlike the detoured-extension wiring part 63 of the meandering shape, so that the noises to be irradiated from the equal-length wires 12 can be reduced. Moreover, the swirl-shaped detoured-extension wiring part 14 does not need a wide space as a whole so that the space of the plural equal-length wires 12 provided on the main control substrate 11 can also be reduced.

According to the equal-length wiring structure of the first embodiment, on the other hand, the detoured-extension wiring part 14 or the part of the swirl-shaped wire is provided substantially at the same portion in the longitudinal direction of each equal-length wires 12. As a result, another circuit can be easily arranged in that space 18 on the main control substrate 11, in which the equal-length wire 12 is not provided, so that the space 18 on the main control substrate 11 can be effectively exploited.

According to the equal-length wiring structure of the first embodiment, moreover, the substrate is the main control substrate 11 so that the radiation noises on the main control substrate 11 can be efficiently reduced.

Here, the invention should not be limited in scope to the embodiments but can be applied other various embodiments so long as it is not contrary to the definition of the claims. In the first embodiment of the invention, for example, the CPU 10 executes the logical operation by the synchronous type control and transmits the data signals and the address signals, which are synchronized with the clock signals, to the RAM 13. However, the invention should not be limited thereto, but even other signals transmitted from the CPU 10 can be applied if they are synchronized ones. If these synchronized signals can be transmitted, the CPU 10 may be replaced by other electronic parts (or circuits).

In the first embodiment, moreover, the synchronized signals are received by the RAM 13. However, the invention should not be limited thereto, but it is needless to say that the RAM 13 may be replaced by other electronic parts (or circuits).

In the first embodiment, moreover, the detoured-extension wiring part 14c is wound twice clockwise, and the detoured-extension wiring part 14b is wound once clockwise. However, the invention should not be limited thereto, but the detoured-extension wiring parts may be wound any time so long as the difference between the wiring lengths of the equal-length wires can be adjusted. Moreover, the wiring parts may also be wound counter-clockwise.

In the first embodiment, moreover, the detoured-extension wiring parts 14b and 14c are provided at the substantially identical portions in the longitudinal direction. However, the invention should not be limited thereto, but the detoured-extension wiring parts may also be provided at longitudinally different portions. In this modification, however, the detoured-extension wiring parts 14b and 14c are provided in one row in the longitudinal direction. Therefore, the spaces 18a and 18b of the main control substrate 11, in which the equal-length wires 12 are not provided, have the substantially rectangular shapes so that the remaining circuits of the main control substrate 11 can be easily arranged in those spaces 18a and 18b. As a result, the space 18 can be effectively exploited. If, moreover, the number of the equal-length wires 12 is increased, the detoured-extension wiring parts 14b and 14b and the detoured-extension wiring parts 14d, 14e and 14f to be formed as the number of the equal-length wires 12 increases are provided in one longitudinal row so that the spaces 18a and 18b can be formed into the substantially rectangular shapes thereby to arrange other circuits of the main control substrate 11 easily therein.

In the second embodiment, on the other hand, the detoured-extension wiring part 35 is constituted to include the turned parts 30, the straight part 31 and the curved parts 32. However, the invention should not be limited thereto, but the invention can also be applied even if the structure does not have the curved parts 32. However, the curved parts 32, if any, can make the reflections hard to occur thereby to make the reflection noises less.

The invention can be applied to the recording apparatus such as a printer, a facsimile apparatus or a copy apparatus, if the recording apparatus is equipped with the substrate or the like, which has the detoured-extension wiring part formed midway of the plural equal-length wires between one circuit for transmitting the synchronized signals and another circuit for receiving the signals.

What is claimed is:

1. A wiring structure comprising:
a substrate;
a first circuit and a second circuit, provided on the substrate;
a first wire, provided on the substrate, and connecting the first circuit and the second circuit, the first wire having a first length; and
a second wire, provided on the substrate, and connecting the first circuit and the second circuit, the second wire having the first length and including a first swirled part.

2. The wiring structure according to claim 1, further comprising
a third wire, provided on the substrate, and connecting the first circuit and the second circuit, the third wire having the first length and including a second swirled part, wherein
the first swirled part and the second swirled part are arrayed in a first direction.

3. The wiring structure according to claim 2, wherein
the first wire includes a first part extending in the first direction and a second part extending in a second direction different from the first direction, and
a length of the first part is longer than a length of the second part.

4. The wiring structure according to claim 1, wherein
the substrate includes a main control substrate.

5. A recording apparatus, operable to record information to a medium, thereby recording is performed, the recording apparatus comprising:
a controller, operable to control the recording; and
the wiring structure according to claim 1, provided in the controller.

6. An electronic apparatus, operable to perform a predetermined operation, the electronic apparatus comprising:
a controller, operable to control the predetermined operation; and
the wiring structure according to claim 1, provided in the controller.
